(19) United States
(12) Patent Application Publication
(10) Pub. No.: US 2025/0266061 A1
(43) Pub. Date: Aug. 21, 2025

(54) DISK DEVICE

(71) Applicants: Kabushiki Kaisha Toshiba, Tokyo (JP); Toshiba Electronic Devices & Storage Corporation, Tokyo (JP)

(72) Inventors: Hayato Yamaguchi, Sagamihara Kanagawa (JP); Nobuhiro Yamamoto, Yokohama Kanagawa (JP); Taichi Okano, Yokohama Kanagawa (JP); Masahide Takazawa, Hachioji Tokyo (JP)

(21) Appl. No.: 18/824,283

(22) Filed: Sep. 4, 2024

(30) Foreign Application Priority Data
Feb. 15, 2024 (JP) 2024-021139

(51) Int. Cl. G11B 33/14; H05K 1/02; H05K 1/11

(52) U.S. Cl. CPC G11B 33/14; H05K 1/0215; H05K 1/115

(57) ABSTRACT

A disk device according to an embodiment includes a housing, a magnetic disk, a printed wiring board, and a film. The housing is provided with an internal space filled with gas different from air and a penetration hole that makes the internal space communicate with an outside. The magnetic disk is disposed in the internal space. The printed wiring board includes a first surface attached to the housing, a second surface located opposite to the first surface, and a side surface provided between an outer edge of the first surface and an outer edge of the second surface. The printed wiring board is configured to seal the penetration hole. The film covers the side surface.

### CROSS-REFERENCE TO RELATED APPLICATIONS

This application is based upon and claims the benefit of priority from Japanese Patent Application No. 2024-021139, filed on Feb. 15, 2024; the entire contents of which are incorporated herein by reference.

### FIELD

Embodiments described herein relate generally to a disk device.

### BACKGROUND

A disk device such as a hard disk drive (HDD) includes, for example, a housing, a magnetic disk, and a printed wiring board (PWB). The magnetic disk is disposed in an internal space of the housing. The internal space of the housing may be filled with gas such as helium different from air. In this case, the PWB seals a penetration hole of the housing.

An insulating part of the PWB is exposed on a side surface of the PWB. Dust may fall off or outgas may be released from the exposed insulating part.

### BRIEF DESCRIPTION OF THE DRAWINGS

FIG. 1 is an exemplary perspective view illustrating an HDD according to a first embodiment in an exploded manner;

FIG. 2 is an exemplary perspective view illustrating the HDD of the first embodiment in an exploded manner from a direction different from that in FIG. 1;

FIG. 3 is an exemplary plan view illustrating a part of a housing and a relay board of the first embodiment;

FIG. 4 is an exemplary cross-sectional view illustrating a part of the HDD of the first embodiment along a line F4-F4 of FIG. 3;

FIG. 5 is an exemplary plan view illustrating a PWB in a manufacturing process of the first embodiment;

FIG. 6 is an exemplary plan view illustrating a part of a housing and a relay board according to a second embodiment;

FIG. 7 is an exemplary plan view illustrating a part of a housing and a relay board according to a third embodiment;

FIG. 8 is an exemplary cross-sectional view illustrating a part of an HDD according to a fourth embodiment;

FIG. 9 is an exemplary cross-sectional view illustrating a part of an HDD according to a fifth embodiment; and

FIG. 10 is an exemplary cross-sectional view illustrating a part of an HDD according to a sixth embodiment.

### DETAILED DESCRIPTION

In general, according to an embodiment, a disk device includes a housing, a magnetic disk, a printed wiring board, and a film. The housing is provided with an internal space filled with gas different from air and a penetration hole that makes the internal space communicate with an outside. The magnetic disk is disposed in the internal space. The printed wiring board includes a first surface attached to the housing, a second surface located opposite to the first surface, and a side surface provided between an outer edge of the first surface and an outer edge of the second surface. The printed wiring board is configured to seal the penetration hole. The film covers the side surface.

### First Embodiment

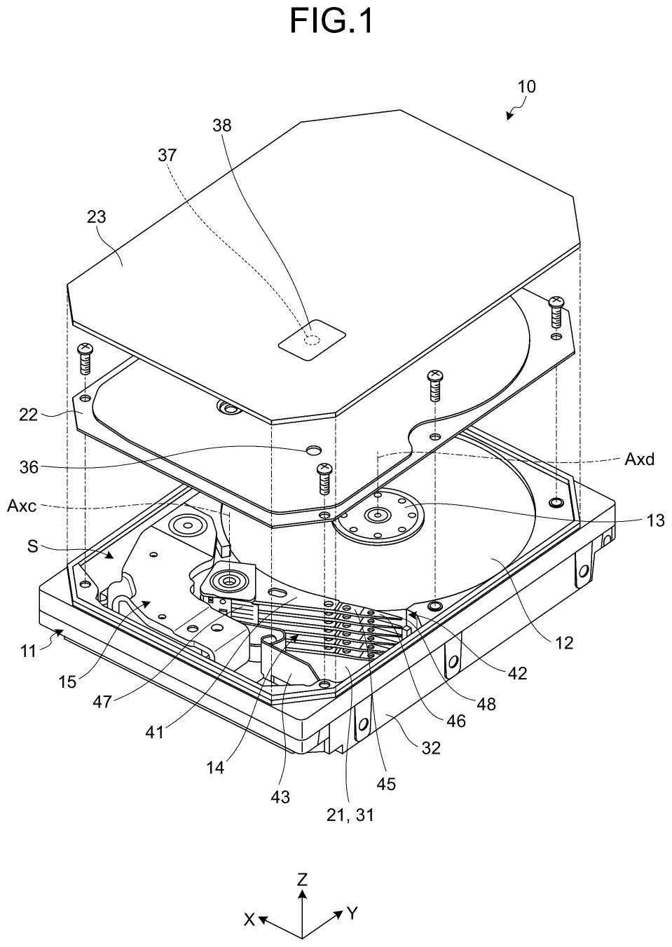

Hereinafter, a first embodiment will be described with reference to FIGS. 1 to 5. Note that, in the present specification, component elements according to embodiments and descriptions of the elements may be described in a plurality of expressions. The component elements and the description thereof are examples, and are not limited by the expression of the present specification. The component elements may also be identified with names different from those in the present specification. In addition, the component elements may be described by an expression different from the expression in the present specification.

In the following description, “suppress” is defined as, for example, preventing the occurrence of an event, an action, or an influence, or reducing the degree of the event, the action, or the influence. In addition, in the following description, “restrict” is defined as, for example, preventing movement or rotation, or allowing movement or rotation within a predetermined range and preventing movement or rotation beyond the predetermined range.

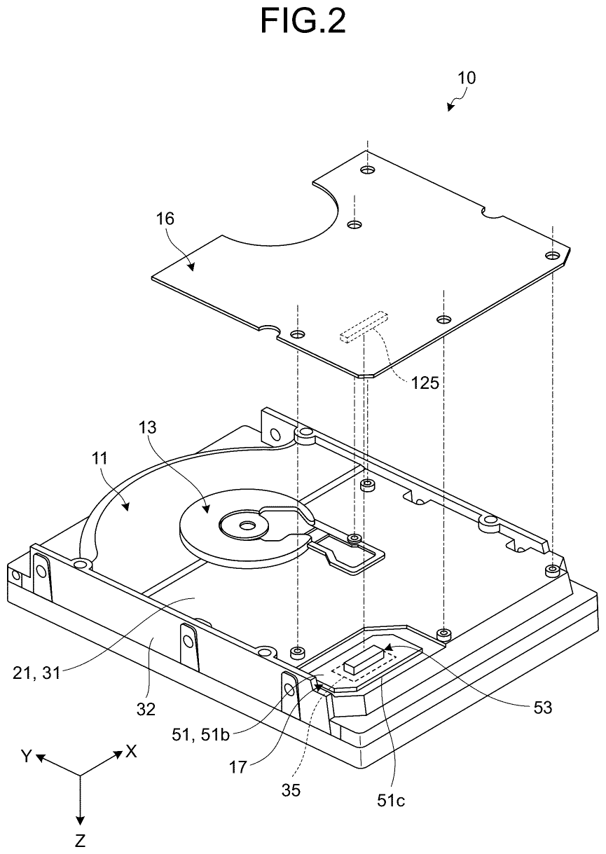

FIG. 1 is an exemplary perspective view illustrating a hard disk drive (HDD) 10 according to a first embodiment in an exploded manner. FIG. 2 is an exemplary perspective view illustrating the HDD 10 of the first embodiment in an exploded manner from a direction different from that in FIG. 1. The HDD 10 is an example of a disk device, and may also be referred to as an electronic device, a storage device, an external storage device, or a magnetic disk device.

As illustrated in the drawings, in the present specification, an X axis, a Y axis, and a Z axis are defined for convenience. The X axis, the Y axis, and the Z axis are orthogonal to each other. The X axis is provided along the width of the HDD 10. The Y axis is provided along the length of the HDD 10. The Z axis is provided along the thickness of the HDD 10.

Furthermore, in the present specification, an X direction, a Y direction, and a Z direction are defined. The X direction is a direction along the X axis and includes a +X direction indicated by an arrow of the X axis and a −X direction which is an opposite direction of the arrow of the X axis. The Y direction is a direction along the Y axis, and includes a +Y direction indicated by an arrow of the Y axis and a −Y direction which is an opposite direction of the arrow of the Y axis. The Z direction is a direction along the Z axis and includes a +Z direction indicated by an arrow of the Z axis and a −Z direction which is an opposite direction of the arrow of the Z axis.

As illustrated in FIG. 1, the HDD 10 includes a housing 11, a plurality of magnetic disks 12, a spindle motor 13, a head stack assembly (HSA) 14, and a voice coil motor (VCM) 15. The magnetic disk 12 may also be referred to as a disk or a platter. As illustrated in FIG. 2, the HDD 10 further includes a printed circuit board (PCB) 16 and a relay board 17.

As illustrated in FIG. 1, the housing 11 is formed in a box shape provided with an internal space S. The plurality of magnetic disks 12, the spindle motor 13, the HSA 14, and the VCM 15 are disposed in the internal space S. The housing 11 includes a base 21, an inner cover 22, and an outer cover 23. Note that, the housing 11 is not limited to this example.

Each of the base 21, the inner cover 22, and the outer cover 23 is made of a metal material such as aluminum alloy. Note that, the materials of the base 21, the inner cover 22, and the outer cover 23 may be different from each other.

The base 21 is formed in a substantially rectangular parallelepiped box shape opened in the +Z direction. The internal space S is provided inside the base 21 and communicates with the outside through an end portion of the base 21 in the +Z direction. The base 21 includes a bottom wall 31 and a side wall 32.

The bottom wall 31 is formed in a substantially rectangular (quadrangular) plate shape disposed to be substantially orthogonal to the Z direction. As illustrated in FIG. 2, a penetration hole 35 is provided in the bottom wall 31. The penetration hole 35 penetrates the bottom wall 31 substantially in the Z direction and makes the internal space S communicate with the outside. The side wall 32 protrudes substantially in the +Z direction from the edge of the bottom wall 31 and is formed in a substantially rectangular frame shape.

As illustrated in FIG. 1, the inner cover 22 is attached to the side wall 32 by a screw, for example. Accordingly, the inner cover 22 covers the internal space S. For example, a gasket is disposed between the inner cover 22 and the side wall 32. The gasket seals a gap between the inner cover 22 and the side wall 32. The outer cover 23 covers the inner cover 22 and is attached to the side wall 32 by welding, for example.

A vent 36 is provided in the inner cover 22. Furthermore, a vent 37 is provided in the outer cover 23. After components are attached to the inside of the base 21 and the inner cover 22 and the outer cover 23 are attached to the base 21, the air in the internal space S is removed from the vents 36 and 37. Furthermore, gas different from air is charged into the internal space S.

The gas with which the internal space S is filled is, for example, low density gas having a density lower than that of air, inert gas having low reactivity, or the like. For example, helium is charged into the internal space. Note that, another fluid may be charged into the inside of the housing 11.

For example, a seal 38 blocks the vent 37 of the outer cover 23. The seal 38 hermetically seals the vent 37 to restrict leakage of the gas with which the internal space S is filled from the vent 37. Note that, the vents 36 and 37 may be sealed by other methods.

The plurality of magnetic disks 12 is arranged in the Z direction with a gap interposed therebetween. The plurality of magnetic disks 12 is formed in a disk shape disposed so as to be substantially orthogonal to the Z direction. A magnetic recording layer is provided on the surface of the magnetic disk 12.

The spindle motor 13 supports the plurality of magnetic disks 12. The plurality of magnetic disks 12 is held by the hub of the spindle motor 13 with, for example, a clamp spring. The spindle motor 13 integrally rotates the plurality of magnetic disks 12 about a central axis Axd.

The central axis Axd is a virtual axis extending substantially in the Z direction. The central axis Axd is, for example, a central axis of the magnetic disk 12 and the spindle motor 13. Note that, the central axis Axd is not limited to this example.

The HSA 14 includes a carriage 41, a plurality of head gimbal assemblies (HGA) 42, and a flexible printed circuit board (FPC) 43. Note that, the HSA 14 is not limited to this example.

The carriage 41 is attached to the base 21 so as to be rotatable about a central axis Axc. The central axis Axc is a virtual axis extending substantially in the Z direction. The central axis Axc is disposed apart from the central axis Axd.

The plurality of HGAs 42 is attached to an arm of the carriage 41 and rotates integrally with the carriage 41 about the central axis Axc. The plurality of HGAs 42 is arranged in the Z direction with a gap interposed therebetween. Each of the plurality of HGAs 42 includes a base plate 45, a load beam 46, a flexure 47, and a magnetic head 48. The magnetic head 48 may also be referred to as a slider.

The base plate 45 and the load beam 46 are made of, for example, stainless steel. The base plate 45 is formed in a plate shape and is attached to the arm of the carriage 41. The load beam 46 is formed in a plate shape thinner than the base plate 45. The load beam 46 is attached to the base plate 45.

The flexure 47 is a kind of flexible printed wiring board formed in an elongated belt shape. The flexure 47 includes, for example, a metal backing plate, an insulating base layer, a conductive layer, and an insulating cover layer.

The flexure 47 extends along the carriage 41, the base plate 45, and the load beam 46. A rotatable gimbal portion is provided at one end portion of the flexure 47. The magnetic head 48 is mounted on the gimbal portion of the flexure 47. Therefore, the magnetic head 48 moves with respect to the magnetic disk 12 in accordance with rotation of the carriage 41.

The magnetic head 48 records and reproduces information with respect to a corresponding one of the plurality of magnetic disks 12. In other words, the magnetic head 48 reads and writes information from and to the magnetic disk 12.

One end portion of the FPC 43 is attached to the carriage 41. The other end portions of the plurality of flexures 47 are connected to the FPC 43. Therefore, the flexure 47 electrically connects the magnetic head 48 and the FPC 43. The other end portion of the FPC 43 is attached to the bottom wall 31. A part of the FPC 43 is bent between the carriage 41 and the bottom wall 31 in accordance with rotation of the carriage 41.

The VCM 15 moves the magnetic head 48 to a desired position along the magnetic disk 12 by rotating the carriage 41 around the central axis Axc. The VCM 15 includes a voice coil, a pair of yokes, and a magnet provided on the yokes. The voice coil is held by the carriage 41.

As illustrated in FIG. 2, the PCB 16 and the relay board 17 are disposed outside the internal space S and attached to the bottom wall 31. The relay board 17 is located between the PCB 16 and the bottom wall 31. Note that, the relay board 17 may be disposed in the internal space S.

The PCB 16 includes various electronic components such as an interface (I/F) connector connected to a host computer and a controller that controls the operation of the HDD 10.

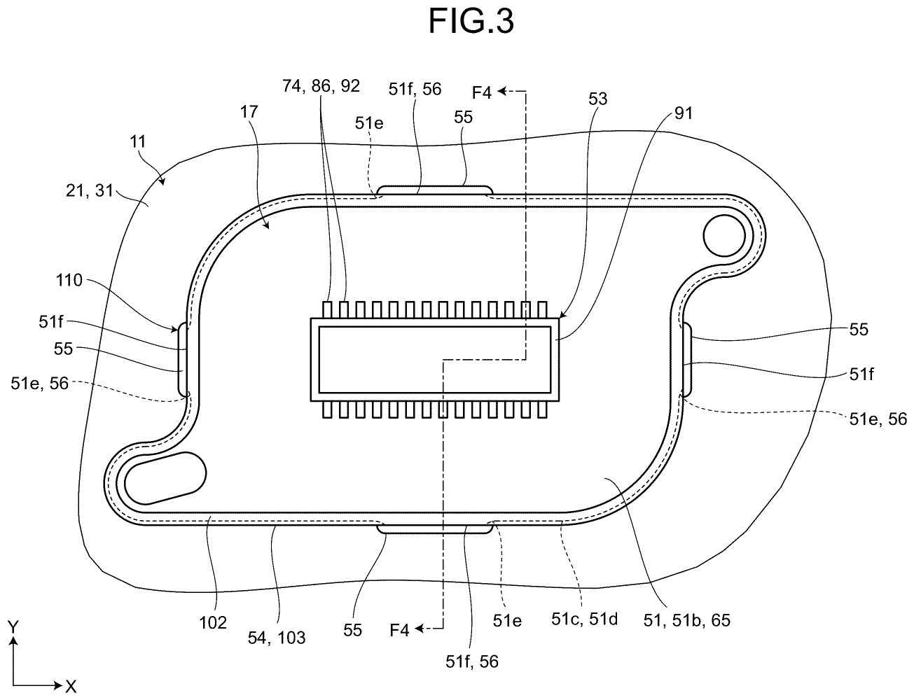

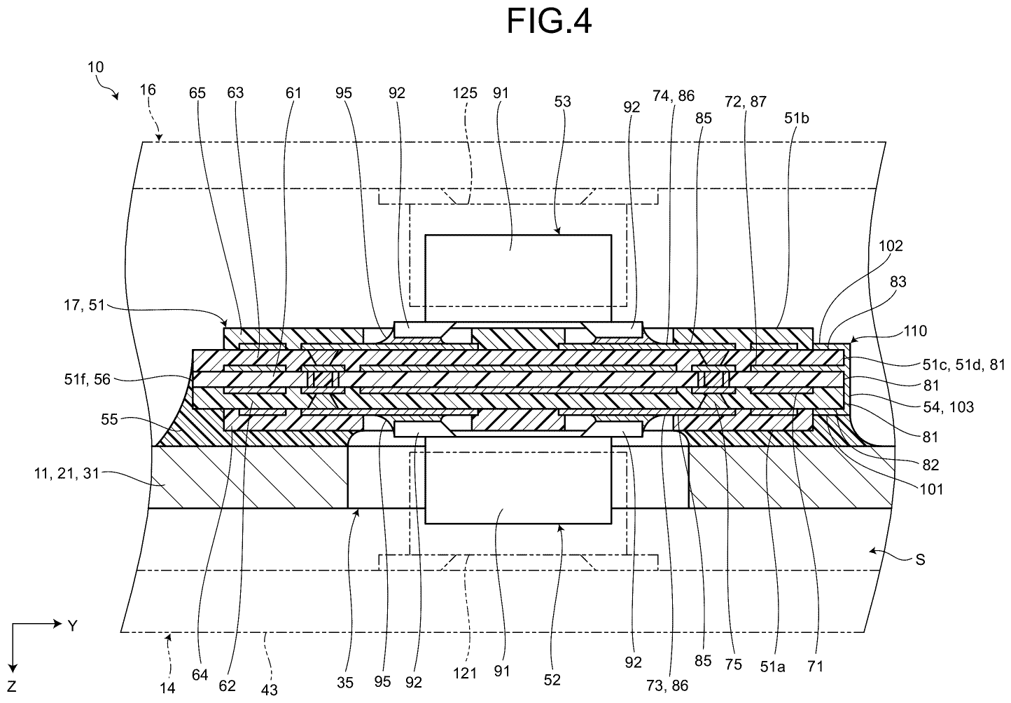

FIG. 3 is an exemplary plan view illustrating a part of the housing 11 and the relay board 17 of the first embodiment. FIG. 4 is an exemplary cross-sectional view illustrating a part of the HDD 10 of the first embodiment along a line F4-F4 of FIG. 3. FIG. 4 virtually illustrates the HSA 14 and the PCB 16 by two-dot chain lines for convenience. As illustrated in FIG. 4, the relay board 17 connects the PCB 16 and the FPC 43.

The relay board 17 includes a printed wiring board (PWB) 51, two relay connectors 52 and 53, and a plating 54. Note that, the relay board 17 is not limited to this example. The relay connectors 52 and 53 are examples of electronic components and connectors. The plating 54 is an example of a metal film.

The HDD 10 further includes an adhesive 55. The adhesive 55 is made of synthetic resin, and is an example of a resin film. The PWB 51 is bonded to the bottom wall 31 of the housing 11 by the adhesive 55 to hermetically seal the penetration hole 35. The PWB 51 includes a first surface 51a, a second surface 51b, and a side surface 51c.

Each of the first surface 51a and the second surface 51b is formed to be substantially flat. The first surface 51a faces substantially in the +Z direction. The first surface 51a faces the bottom wall 31 and the penetration hole 35, and is attached to the bottom wall 31 of the housing 11 by the adhesive 55. That is, the adhesive 55 bonds the first surface 51a and the housing 11 to each other. The second surface 51b is located opposite to the first surface 51a. The second surface 51b faces the PCB 16.

The side surface 51c is provided between the outer edge of the first surface 51a and the outer edge of the second surface 51b. The side surface 51c faces a direction substantially orthogonal to the Z axis. In other words, the side surface 51c faces the direction along the first surface 51a.

As illustrated in FIG. 3, the side surface 51c includes a plurality of regions 51d, 51e, and 51f. Each of the regions 51d, 51e, and 51f is a part of the side surface 51c. In addition, the PWB 51 further includes four protrusions 56.

Each of the four protrusions 56 protrudes from the region 51d. The regions 51e and 51f are provided in each of the four protrusions 56. That is, the protrusion 56 includes a part of the side surface 51c. The region 51e is connected to the region 51d. The region 51f is provided at the end portion of the protrusion 56 and connected to the region 51e.

As illustrated in FIG. 4, the PWB 51 of the present embodiment is, for example, a rigid board such as a glass epoxy board and is a build-up board. Note that, the PWB 51 may be another rigid board or a flexible printed wiring board. The PWB 51 includes five insulating layers 61, 62, 63, 64, and 65, four conductive layers 71, 72, 73, and 74, and a plurality of vias 75. Note that, the PWB 51 is not limited to this example.

At least one of the insulating layers 61, 62, and 63 may also be referred to as an insulating substrate. Each of the insulating layers 61, 62, and 63 includes, for example, glass fiber and synthetic resin such as an epoxy resin or polyimide (PI). Note that, the insulating layers 61, 62, and 63 are not limited to this example. The insulating layers 64 and 65 are solder resists, for example.

The five insulating layers 61, 62, 63, 64, and 65 are stacked in the Z direction. The insulating layer 61 is located between the two insulating layers 62 and 63. The insulating layer 62 is located between the two insulating layers 61 and 64. The insulating layer 63 is located between the two insulating layers 61 and 65.

Each of the insulating layers 61, 62, and 63 includes an end surface 81 in the direction along the first surface 51a. The side surface 51c of the PWB 51 includes the end surfaces 81 of the insulating layers 61, 62, and 63. The side surface 51c may further include at least one end surface of the insulating layers 64 and 65 and the conductive layers 71, 72, 73, and 74.

The insulating layer 62 further includes a surface 82. The surface 82 is formed to be substantially flat and faces substantially in the +Z direction. The insulating layer 64 covers the surface 82. The insulating layer 63 further includes a surface 83. The surface 83 is formed to be substantially flat and faces substantially in the −Z direction. The insulating layer 65 covers the surface 83.

Each of the conductive layers 71, 72, 73, and 74 is made of a metal material such as copper, for example. The conductive layer 71 is provided between the two insulating layers 61 and 62. The conductive layer 72 is provided between the two insulating layers 61 and 63. The conductive layer 73 is provided on the surface 82, and is located between the two insulating layers 62 and 64. The conductive layer 74 is provided on the surface 83, and is located between the two insulating layers 63 and 65.

Each of the conductive layers 71, 72, 73, and 74 includes at least one of a wiring 85, a pad 86, and a ground plane 87. The ground plane 87 is an example of a conductor set to ground potential. Each of the conductive layers 73 and 74 includes a plurality of pads 86.

Each of the plurality of vias 75 penetrates at least one of the plurality of insulating layers 61, 62, and 63, and connects at least two of the four conductive layers 71, 72, 73, and 74 to each other. Each of the plurality of vias 75 is a blind via or a buried via, for example. The plurality of pads 86 of the conductive layer 73 and the plurality of pads 86 of the conductive layer 74 are electrically connected to each other through the plurality of vias 75.

The insulating layer 64 covers the wiring 85 and the ground plane 87 of the conductive layer 73. For example, the insulating layer 64, the exposed surface 82 of the insulating layer 62, and the exposed pads 86 of the conductive layer 73 form the first surface 51a of the PWB 51. In other words, the pads 86 of the conductive layer 73 are provided on the first surface 51a of the PWB 51.

The insulating layer 65 covers the wiring 85 and the ground plane 87 of the conductive layer 74. For example, the insulating layer 65, the exposed surface 83 of the insulating layer 63, and the exposed pads 86 of the conductive layer 74 form the second surface 51b of the PWB 51. In other words, the pads 86 of the conductive layer 74 are provided on the second surface 51b of the PWB 51.

Each of the two relay connectors 52 and 53 includes a frame 91 and a plurality of leads 92. The frame 91 is made of synthetic resin, for example. The lead 92 is made of a metal material and attached to the frame 91.

The plurality of leads 92 is connected to the pads 86 by solder 95, for example. The relay connector 52 is mounted on the first surface 51a of the PWB 51 by connecting the leads 92 to the pads 86 of the conductive layer 73. The relay connector 52 is disposed in the penetration hole 35. A relay connector 53 is mounted on the second surface 51b of the PWB 51 by connecting the leads 92 to the pads 86 of the conductive layer 74.

Similarly to the conductive layers 71, 72, 73, and 74, the plating 54 is made of a metal material such as copper. Note that, the material of the plating 54 and the materials of the conductive layers 71, 72, 73, and 74 may be different from each other.

The plating 54 is electrically connected to the ground plane 87. For example, the plating 54 and the ground plane 87 are integrally formed. The plating 54 may be electrically connected to the ground plane 87 through the wiring 85, for example.

The plating 54 includes two surface plating 101 and 102 and side surface plating 103. Each of the surface plating 101 and 102 is connected to the side surface plating 103. Note that, in the plating 54, at least one of the surface plating 101 and 102 may be omitted.

The surface plating 101 covers a part of the first surface 51a. For example, the surface plating 101 covers the exposed surface 82 of the insulating layer 62 and adheres to the surface 82. In the present embodiment, the surface plating 101 is formed in a frame shape extending along the outer edge of the first surface 51a of the PWB 51, and covers the entire region of the outer edge of the first surface 51a.

The surface plating 102 covers a part of the second surface 51b. For example, the surface plating 102 covers the exposed surface 83 of the insulating layer 63 and adheres to the surface 83. As illustrated in FIG. 3, the surface plating 102 of the present embodiment is formed in a frame shape extending along the outer edge of the second surface 51b of the PWB 51, and covers the entire region of the outer edge of the second surface 51b.

The side surface plating 103 covers at least a part of the side surface 51c. For example, the side surface plating 103 covers the regions 51d and 51e of the side surface 51c. In the present embodiment, the side surface plating 103 does not cover the region 51f of the side surface 51c and is separated from the region 51f. Note that, the side surface plating 103 is not limited to this example.

The regions 51d and 51e of the side surface 51c covered with the side surface plating 103 are larger than the region 51f of the side surface 51c separated from the side surface plating 103 without being covered with the side surface plating 103. Note that, the side surface 51c is not limited to this example.

As illustrated in FIG. 4, a part of the adhesive 55 covers the region 51f of the side surface 51c. The plating 54 and the adhesive 55 form a protective film 110. That is, the HDD 10 includes the protective film 110 covering the side surface 51c. The protective film 110 includes the metal plating 54 and the adhesive 55 made of resin. Note that, the protective film 110 is not limited to this example. The protective film 110 is an example of a film. Instead of the adhesive 55, another resin film may cover the side surface 51c.

In the present embodiment, the protective film 110 covers the substantially entire region of the side surface 51c. That is, the regions 51d, 51e, and 51f of the side surface 51c covered with the protective film 110 are larger than the region of the side surface 51c separated from the protective film 110 without being covered with the protective film 110.

The HSA 14 further includes a relay connector 121 mounted at the end portion of the FPC 43. The relay connector 121 is connected to the relay connector 52. Accordingly, the PWB 51 is electrically connected to the magnetic head 48 through the relay connectors 52 and 121, the FPC 43, and the flexure 47. That is, the FPC 43 electrically connects the magnetic head 48 and the PWB 51.

The PCB 16 further includes a relay connector 125. The relay connector 125 is connected to the relay connector 53. As a result, a controller of the PCB 16 is electrically connected to the magnetic head 48 through the relay connectors 125 and 53, the PWB 51, the relay connectors 52 and 121, the FPC 43, and the flexure 47.

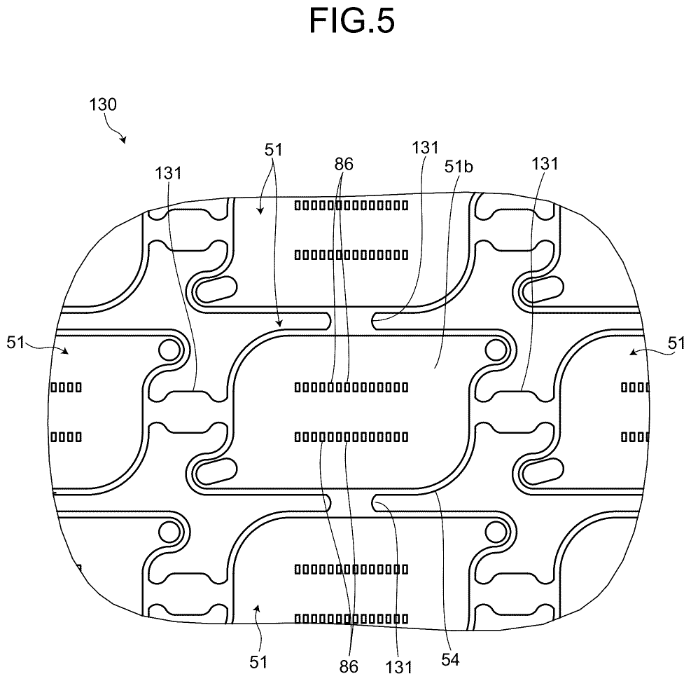

FIG. 5 is an exemplary plan view illustrating the PWB 51 in the manufacturing process of the first embodiment. As illustrated in FIG. 5, in the manufacturing process of the PWB 51, a panel 130 is manufactured by a build-up method. The panel 130 includes a plurality of PWBs 51 and a plurality of suspenders 131. The PWB 51 and the suspender 131 are integrally formed.

Each of the plurality of suspenders 131 connects two adjacent PWBs 51 of the plurality of PWBs 51 to each other. For example, when the suspender 131 is cut by a router bit, the plurality of PWBs 51 is separated from the panel 130.

The protrusion 56 is, for example, a part of the suspender 131 cut by the router bit. The region 51f of the side surface 51c is a surface of the protrusion 56 formed by cutting with a router bit. Therefore, the region 51f is not covered with the plating 54.

When the relay board 17 is attached to the bottom wall 31 of the housing 11, for example, a dispenser supplies the adhesive 55 between the bottom wall 31 and the first surface 51a. Furthermore, the dispenser applies the adhesive 55 to the region 51f. As a result, the region 51f exposed by cutting is covered with the adhesive 55.

As illustrated in FIG. 4, the side surface 51c of the PWB 51 includes the end surfaces 81 of the plurality of insulating layers 61, 62, and 63. That is, at least a part of the side surface 51c includes glass fiber and synthetic resin which are materials of the insulating layers 61, 62, and 63.

When the side surface 51c is exposed, from the side surface 51c, dust such as fine particles of glass fiber or synthetic resin may fall off, or outgas may be released. However, by covering the side surface 51c, the protective film 110 of the present embodiment suppresses falling of dust from the side surface 51c and suppresses release of outgas from the side surface 51c. Therefore, the protective film 110 suppresses contamination of a manufacturing device such as a curing furnace or the HDD 10 due to the dust and the outgas.

In the HDD 10 according to the first embodiment described above, the internal space S and the penetration hole 35 are provided in the housing 11. The internal space S is filled with gas different from air. The penetration hole 35 makes the internal space S communicate with the outside. The magnetic disk 12 is provided in the internal space S. The PWB 51 includes the first surface 51a, the second surface 51b, and the side surface 51c, and is configured to seal the penetration hole 35. The first surface 51a is attached to the housing 11. The second surface 51b is located opposite to the first surface 51a. The side surface 51c is provided between the outer edge of the first surface 51a and the outer edge of the second surface 51b. The protective film 110 covers the side surface 51c.

In general, the PWB 51 includes an insulating layer. The insulating layer includes glass fiber and synthetic resin, for example. When the side surface 51c of the PWB 51 is exposed, dust such as glass fiber or synthetic resin may fall off, or outgas may be released from the side surface 51c. By covering the side surface 51c with the protective film 110, the HDD 10 can suppress falling of dust and release of outgas from the side surface 51c. As a result, the HDD 10 can suppress contamination of a manufacturing device of the PWB 51, and eventually, can suppress entry of dust into the internal space S in the manufacturing device.

The protective film 110 includes the plating 54 which is a metal film. Metal is generally less permeable to gas than resin. Therefore, the plating 54 can more reliably suppress release of outgas from the side surface 51c. In addition, the plating 54 can be formed simultaneously with the conductive layers 71, 72, 73, and 74 and the via 75 of the PWB 51, for example. Therefore, the HDD 10 can facilitate manufacturing of the PWB 51 and the protective film 110.

The metal protective film 110 is electrically connected to a conductor set to the ground potential. As a result, the metal protective film 110 can suppress generation of noise.

The PWB 51 includes the ground plane 87. The metal protective film 110 is electrically connected to the ground plane 87. For example, the metal protective film 110 can include copper foil extending from the ground plane 87. Therefore, the HDD 10 can facilitate manufacturing of the PWB 51 and the protective film 110.

The protective film 110 includes the adhesive 55 which is a resin film. As a result, even if it is difficult to provide a metal film on the side surface 51c of the PWB 51 in the wiring design of the PWB 51, the protective film 110 can cover the side surface 51c.

The adhesive 55 includes a resin film covering the side surface 51c, and bonds the first surface 51a and the housing 11 to each other. That is, the adhesive 55 that bonds the first surface 51a to the housing 11 covers the side surface 51c of the PWB 51. As a result, the HDD 10 can facilitate manufacturing of the PWB 51 and the protective film 110.

The protective film 110 further covers the first surface 51a and the second surface 51b. During manufacturing of the PWB 51, the plurality of PWBs 51 is integrally manufactured and separated from each other. At this time, the protective film 110 may peel off from the side surface 51c. However, since the protective film 110 covers not only the side surface 51c but also the first surface 51a and the second surface 51b, the protective film 110 firmly adheres to the PWB 51. Therefore, peeling of the protective film 110 from the side surface 51c can be suppressed.

The protective film 110 covers the entire region of the outer edge of the first surface 51a and the entire region of the outer edge of the second surface 51b. As a result, the protective film 110 firmly adheres to the PWB 51. Furthermore, since the protective film 110 covers a corner between the side surface 51c and the first surface 51a and a corner between the side surface 51c and the second surface 51b, it is possible to suppress falling of dust and release of outgas from the corner.

The regions 51d, 51e, and 51f of the side surface 51c covered with the protective film 110 are larger than the region of the side surface 51c separated from the protective film 110. As a result, the HDD 10 can more effectively suppress falling of dust and release of outgas from the side surface 51c.

The PWB 51 includes the plurality of the stacked insulating layers 61, 62, and 63. The side surface 51c includes the ends (the end surfaces 81) of the plurality of insulating layers 61, 62, and 63 in the direction along the first surface 51a. That is, the protective film 110 collectively covers the side surface 51c of the PWB 51 that is a multilayer substrate. As a result, the HDD 10 can facilitate manufacturing of the PWB 51 and the protective film 110.

The magnetic head 48 is disposed in the internal space S and is configured to read and write information from and to the magnetic disk 12. The FPC 43 is disposed in the internal space S and electrically connects the magnetic head 48 and the PWB 51. That is, the PWB 51 can electrically connect a component such as a controller outside the internal space S to the magnetic head 48 and seal the penetration hole 35.

The PWB 51 is located outside the internal space S. As a result, the PWB 51 can suppress contamination of the internal space S even if dust falls off and outgas is released from the PWB 51.

### Second Embodiment

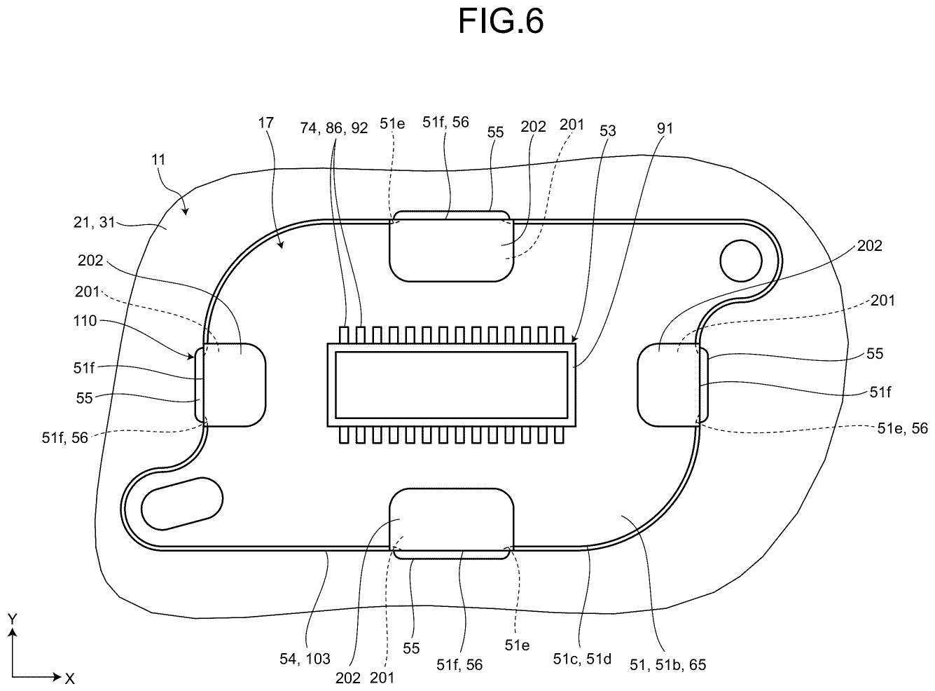

Hereinafter, a second embodiment will be described with reference to FIG. 6. Note that, in the following description of the plurality of embodiments, component elements having functions similar to those of the component elements already described are denoted by the same reference signs as those of the component elements already described, and the description thereof may be omitted. In addition, the plurality of component elements denoted by the same reference signs does not necessarily have all the functions and properties in common, and may have different functions and properties according to each embodiment.

FIG. 6 is an exemplary plan view illustrating a part of the housing 11 and the relay board 17 according to the second embodiment. As illustrated in FIG. 6, the plating 54 of the second embodiment includes a plurality of surface plating 201 and 202 instead of the surface plating 101 and 102. Note that, the surface plating 201 and 202 are substantially equal to the surface plating 101 and 102 except for the points described below.

Four pieces of the surface plating 201 cover the first surface 51a. The four pieces of surface plating 201 are separated from each other and connected to the side surface plating 103 in the vicinity of the four protrusions 56. Therefore, a part of the outer edge of the first surface 51a is exposed without being covered with the plating 54.

The four pieces of surface plating 202 cover the second surface 51b. The four pieces of surface plating 202 are separated from each other and connected to the side surface plating 103 in the vicinity of the four protrusions 56. Therefore, a part of the outer edge of the second surface 51b is exposed without being covered with the plating 54. The four pieces of surface plating 201 and the four pieces of surface plating 202 have substantially the same shape.

In the HDD 10 of the second embodiment described above, the plating 54 is separated from at least one of a part of the outer edge of the first surface 51a and a part of the outer edge of the second surface 51b. That is, the plating 54 does not need to cover the entire region of the outer edge of the first surface 51a and the outer edge of the second surface 51b. As a result, the HDD 10 can improve flexibility in wiring design in the PWB 51.

### Third Embodiment

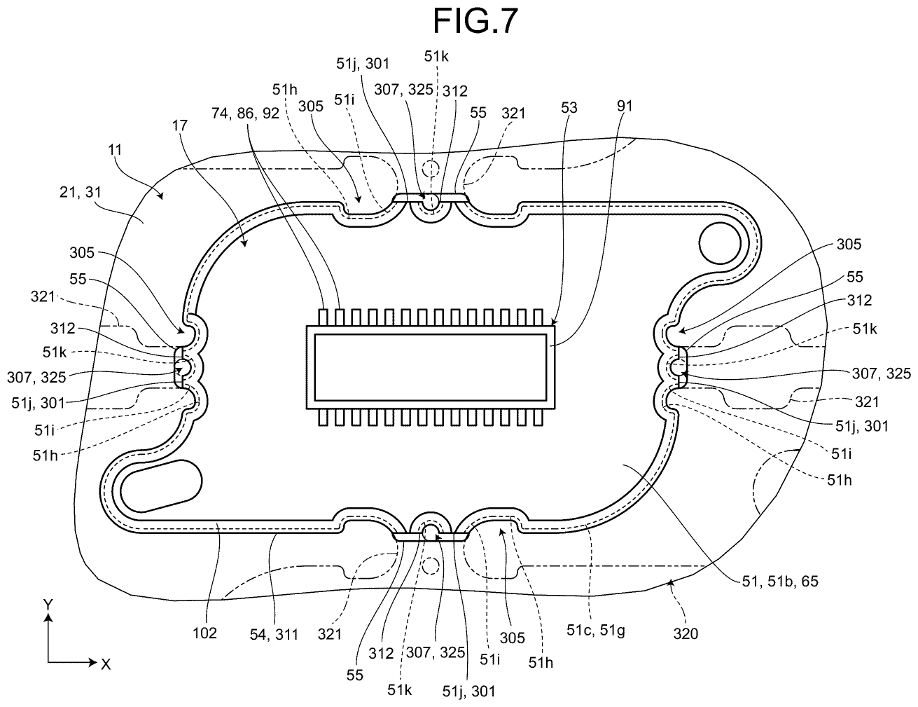

Hereinafter, a third embodiment will be described with reference to FIG. 7. FIG. 7 is an exemplary plan view illustrating a part of the housing 11 and the relay board 17 according to the third embodiment. As illustrated in FIG. 7, the side surface 51c of the third embodiment includes regions 51g, 51h, 511, 51j, 51k instead of the regions 51d, 51e, and 51f. The region 51g is an example of the first region. The region 51h is an example of the second region. Furthermore, the PWB 51 includes four protrusions 301 instead of the four protrusions 56.

Each of the regions 51g, 51h, 511, 51j, and 51k is a part of the side surface 51c. Each of the four regions 51h defines a recess 305. The recess 305 is a notch depressed from the region 51g. The region 51h is connected to the region 51g.

The four protrusions 301 protrude from the four regions 51h. The protrusion 301 is located inside the recess 305. That is, the protrusion 301 does not protrude to the outside of the recess 305 beyond the region 51g.

The regions 511, 51j, and 51k are provided in each of the four protrusions 301. The region 51i is connected to the region 51h. The region 51j is connected to the regions 51i and 51k and is provided between the regions 51i and 51k. The region 51k is a semi-cylindrical curved surface, and defines a notch 307. The notch 307 is recessed from the region 51j.

The plating 54 of the third embodiment includes a plurality of side surface plating 311 and 312 instead of the side surface plating 103. The side surface plating 311 and 312 are substantially equal to the side surface plating 103 except for the points described below.

The side surface plating 311 covers the regions 51g, 51h, and 51i of the side surface 51c. The side surface plating 312 is separated from the side surface plating 311. The side surface plating 312 covers the region 51k of the side surface 51c. The side surface plating 311 and 312 does not cover the region 51j of the side surface 51c and is disposed apart from the region 51j. That is, the protective film 110 covers the region 51g, the region 51h, and a part of the protrusion 301.

FIG. 7 virtually illustrates a panel 320 and a plurality of suspenders 321 of the third embodiment by two-dot chain lines. The panel 320 and the suspender 321 are substantially equal to the panel 130 and the suspender 131 except for the points described below. In the third embodiment, a through hole 325 is provided in the suspender 321. The side surface plating 312 is a conductor of the through hole 325.

For example, the router bit cuts the suspender 321 from the region 51i, which is one side surface of the suspender 321, to the through hole 325. Next, the router bit cuts the suspender 321 from the region 51i, which is the other side surface of the suspender 321, to the through hole 325. As a result, the router bit cuts the suspender 321.

The router bit exerts a force on the plating 54 in a direction of peeling off from the side surface 51c at an end of a portion to be cut. However, by cutting the suspender 321 from both sides thereof, the router bit can suppress peeling of the plating 54 from the side surface 51c.

The router bit cuts the suspender 321 so as to chip a part of the through hole 325. The protrusion 301 is, for example, a part of the suspender 321 cut by the router bit. The notch 307 is a part of the remaining through hole 325. The region 51j of the side surface 51c is a surface of the protrusion 301 formed by cutting with the router bit. Therefore, the region 51j is not covered with the plating 54.

The side surface plating 311 covering the region 51i and the side surface plating 312 covering the region 51k are disposed close to each other. Therefore, the region 51j not covered with the plating 54 is set to be relatively small.

In the HDD 10 of the third embodiment described above, the side surface 51c includes the region 51g and the region 51h. The region 51h forms the recess 305 depressed from the region 51g. The PWB 51 includes the protrusion 301 protruding from the region 51h and located inside the recess 305. The protective film 110 covers the region 51g, the region 51h, and a part of the protrusion 301.

During manufacturing of the PWB 51, the plurality of PWBs 51 is integrally manufactured and separated from each other. For example, the suspender 321 connecting two adjacent PWBs 51 is cut. A part of the suspender 321 remaining in the PWB 51 becomes the protrusion 301. A tool such as a router bit that cuts the suspender 321 can suppress, for example, contact of the tool with the side surface 51c by cutting the suspender 321 (the protrusion 301), and eventually, can reduce the amount of the protective film 110 removed by the tool. Since the protrusion 301 is located inside the recess 305, the protrusion 301 does not protrude beyond the region 51g. Therefore, the protrusion 301 can suppress generation of burr that interferes with other components.

### Fourth Embodiment

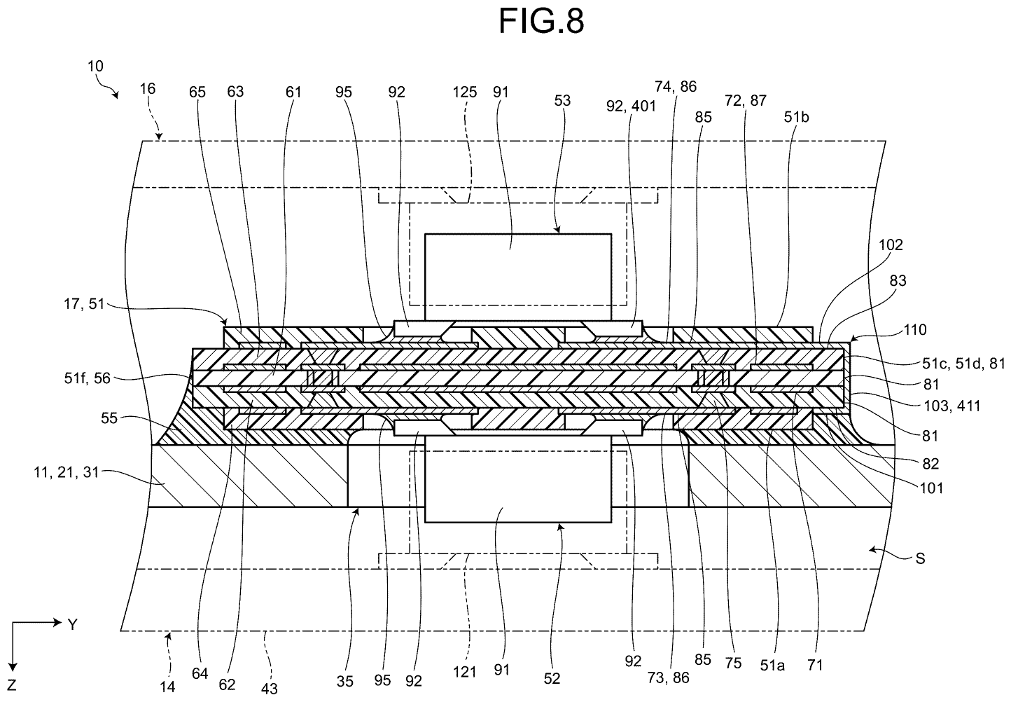

Hereinafter, a fourth embodiment will be described with reference to FIG. 8. FIG. 8 is an exemplary cross-sectional view illustrating a part of the HDD 10 according to the fourth embodiment. As illustrated in FIG. 8, the plurality of leads 92 of the fourth embodiment includes a ground line 401. The ground line 401 is an example of a terminal.

The ground line 401 is set to the ground potential. The ground line 401 is connected, by the solder 95, to one of the plurality of pads 86 set to the ground potential. The ground line 401 is electrically connected to another ground such as the base 21 through, for example, the relay connector 121 or the relay connector 125.

The protective film 110 of the fourth embodiment includes plating 411 instead of the plating 54. The plating 411 is substantially equal to the plating 54 except for the points described below. The plating 411 is electrically connected to the ground line 401 through, for example, the wiring 85 and the pad 86. Therefore, the plating 411 is electrically connected to a conductor set to the ground potential.

In the fourth embodiment, the adhesive 55 may be conductive. For example, the adhesive 55 may include metal filler. The adhesive 55 bonds the plating 411 and the base 21 to each other and electrically connects the plating 411 and the base 21. Therefore, the plating 411 is electrically connected to the base 21, which is ground, through the conductive adhesive 55.

In the HDD 10 of the fourth embodiment described above, the relay connector 53 includes the ground line 401 and is mounted on the PWB 51. The ground line 401 is set to the ground potential. The plating 411 is electrically connected to the ground line 401. Thus, the plating 411 can be electrically connected to the ground outside the PWB 51.

### Fifth Embodiment

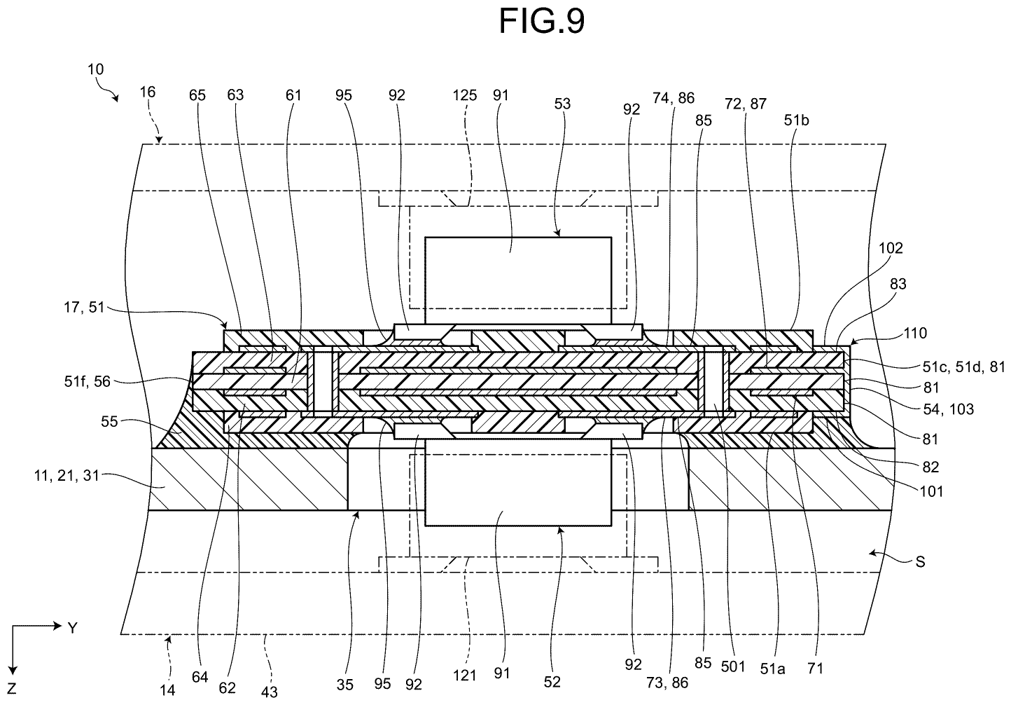

Hereinafter, a fifth embodiment will be described with reference to FIG. 9. FIG. 9 is an exemplary cross-sectional view illustrating a part of the HDD 10 according to the fifth embodiment. As illustrated in FIG. 9, a plurality of through holes 501 is provided in the PWB 51 of the fifth embodiment.

The through hole 501 connects the two conductive layers 73 and 74. The through hole 501 is disposed apart from the penetration hole 35 in the direction along the first surface 51a. In other words, the through hole 501 is located outside the inner edge of the penetration hole 35. Therefore, the bottom wall 31 of the housing 11 covers the through hole 501.

In the HDD 10 of the fifth embodiment described above, the through hole 501 is provided in the PWB 51. The through hole 501 is disposed apart from the penetration hole 35 in the direction along the first surface 51a. As a result, the PWB 51 can suppress the through hole 501 making the internal space S communicate with the outside.

### Sixth Embodiment

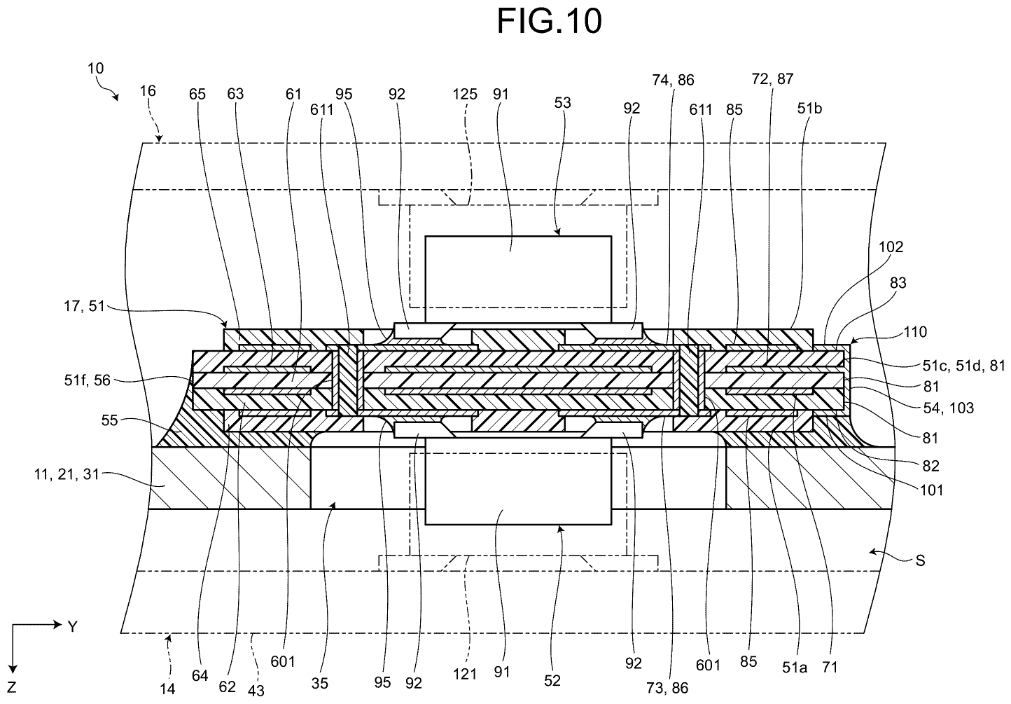

Hereinafter, a sixth embodiment will be described with reference to FIG. 10. FIG. 10 is an exemplary cross-sectional view illustrating a part of the HDD 10 according to the sixth embodiment. As illustrated in FIG. 10, a plurality of through holes 601 is provided in the PWB 51 of the sixth embodiment.

The through hole 601 connects the two conductive layers 73 and 74. The through hole 601 overlaps the penetration hole 35 in the Z direction. Note that, the through hole 601 may be disposed apart from the penetration hole 35.

The PWB 51 of the sixth embodiment further includes resin 611. The resin 611 is, for example, epoxy resin or synthetic resin such as PI. The through hole 601 is filled with the resin 611. As a result, the resin 611 hermetically seals the through hole 601.

In the HDD 10 of the sixth embodiment described above, the through hole 601 is provided in the PWB 51. The PWB 51 includes the resin 611 with which the through hole 601 is filled. As a result, the PWB 51 can suppress the through hole 601 making the internal space S communicate with the outside.

The structures of the fourth to sixth embodiments described above may be applied to any of the first to third embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A disk device comprising:
a housing provided with an internal space filled with gas different from air and a penetration hole that makes the internal space communicate with an outside;
a magnetic disk disposed in the internal space;
a printed wiring board including a first surface attached to the housing, a second surface located opposite to the first surface, and a side surface provided between an outer edge of the first surface and an outer edge of the second surface, the printed wiring board being configured to seal the penetration hole; and
a film covering the side surface.

2. The disk device according to claim 1, wherein
the film includes a metal film.

3. The disk device according to claim 2, wherein
the metal film is electrically connected to a conductor set to ground potential.

4. The disk device according to claim 3, wherein
the printed wiring board includes a ground plane, and
the metal film is electrically connected to the ground plane.

5. The disk device according to claim 3, further comprising:
an electronic component that has a terminal set to ground potential and is mounted on the printed wiring board, wherein
the metal film is electrically connected to the terminal.

6. The disk device according to claim 5, wherein
the electronic component is a connector.

7. The disk device according to claim 1, wherein
the film includes a resin film.

8. The disk device according to claim 7, further comprising:
an adhesive including the resin film and bonding the first surface and the housing to each other.

9. The disk device according to claim 1, wherein
the film further covers the first surface and the second surface.

10. The disk device according to claim 9, wherein
the film covers an entire region of the outer edge of the first surface and an entire region of the outer edge of the second surface.

11. The disk device according to claim 1, wherein
the side surface includes a first region and a second region that defines a recess depressed from the first region,
the printed wiring board includes a protrusion protruding from the second region and located inside the recess, and
the film covers the first region, the second region, and a part of the protrusion.

12. The disk device according to claim 1, wherein
the printed wiring board is provided with a through hole, and
the through hole is disposed apart from the penetration hole in a direction along the first surface.

13. The disk device according to claim 1, wherein
the printed wiring board is provided with a through hole and includes resin with which the through hole is filled.

14. The disk device according to claim 1, wherein
a region of the side surface covered with the film is larger than a region of the side surface separated from the film.

15. The disk device according to claim 1, wherein
the printed wiring board includes a plurality of stacked insulating layers, and
the side surface includes ends of the plurality of insulating layers in a direction along the first surface.

16. The disk device according to claim 1, further comprising:
a magnetic head disposed in the internal space and configured to read and write information from and to the magnetic disk; and
a flexible printed circuit board that is disposed in the internal space and electrically connects the magnetic head and the printed wiring board.

17. The disk device according to claim 1, wherein
the printed wiring board is located outside the internal space.

18. A disk device comprising:
a housing provided with a penetration hole;
a magnetic disk disposed inside the housing;
a printed wiring board including a first surface attached to the housing, a second surface located opposite to the first surface, and a side surface provided between an outer edge of the first surface and an outer edge of the second surface, the printed wiring board being configured to seal the penetration hole; and
a film covering the side surface.
